(19) United States
(12) Patent Application Publication
(10) Pub. No.: US 2012/0229159 A1
(43) Pub. Date: Sep. 13, 2012

(54) TEST INTERFACE BOARD AND TEST SYSTEM INCLUDING THE SAME

(76) Inventors: Joon-yeon KIM, Yongin-si (KR); Cheol-jong WOO, Suwon-si (KR); Chang-hyun CHO, Hwaseong-si (KR); Hyung-soon KIM, Bucheon-si (KR)

(21) Appl. No.: 13/404,198

(22) Filed: Feb. 24, 2012

(30) Foreign Application Priority Data
Mar. 8, 2011 (KR) 10-2011-0020623

(51) Int. Cl. G01R 31/00

(52) U.S. Cl. 324/756.07

(57) ABSTRACT

A test interface board includes a wiring group, a plurality of contact portions, and a control device. The wiring group includes a main wire operatively coupled to a channel of a tester, and a plurality of sub-wires operatively coupled to the main wire. The plurality of contact portions are operatively coupled to the plurality of sub-wires, and contact first electrodes of a plurality of semiconductor devices. The control device includes a plurality of switching devices operatively coupled to the plurality of sub-wires, a memory configured to store an identification number, and a controller configured to open and close the plurality of switching devices in response to a control signal corresponding to the identification number from among a plurality of control signals.

### CROSS-REFERENCE TO RELATED APPLICATIONS

This application claims priority under 35 U.S.C. §119 to Korean Patent Application No. 10-2011-0020623, filed on Mar. 8, 2011, the disclosure of which is incorporated by reference herein in its entirety.

### TECHNICAL FIELD

Exemplary embodiments of the inventive concept relate to a test interface board and a test system including the same, and more particularly, to a test interface board including a control device and a test system using the control device.

### DISCUSSION OF THE RELATED ART

During mass production of semiconductors, a test process is performed to detect defects of manufactured semiconductor devices. A tester is used to perform the test process, and the number of channels of the tester may be limited. If a channel of the tester is divided into a plurality of wiring groups connected in parallel to a plurality of devices under test (DUTs), and a switching device is not utilized, all of the DUTs may be falsely determined to be defective if a single DUT is defective. Further, if a channel of the tester is divided into a plurality of wiring groups connected in parallel to a plurality of DUTs, and a switching device is utilized, there may not be adequate space to mount the DUTs and the switching device, and contact errors may occur. In addition, when multiple switching devices are utilized, control bits corresponding to the switching devices are used to control the switching devices. As a result, as the number of switching devices increases, the number of control bits also increases.

### SUMMARY

According to an exemplary embodiment of the inventive concept, there is provided a test interface board for interfacing a plurality of semiconductor devices and a tester used to test the plurality of semiconductor devices. The test interface board may include a first division wiring portion including a first main wiring connected to a first channel of the tester, and a plurality of first sub-wirings divided from the first main wiring. The test interface board may further include a plurality of first contact portions that are respectively connected to the plurality of first sub-wirings and respectively contact first electrodes of the plurality of semiconductor devices. The test interface board may further include a first control device including a plurality of switching devices that are respectively installed in the plurality of first sub-wirings, a memory in which a first identification number is recorded, and a controller that controls the opening and closing of the plurality of switching devices in response to a control signal corresponding to the first identification number from among a plurality of control signals.

The first channel may be a power channel, and each of the plurality of first switching devices may be one of a metal-oxide semiconductor (MOS) transistor and a relay.

The first channel may be a data input/output channel, and each of the plurality of switching devices may be one of a bidirectional buffer, a MOS transistor and a relay.

The memory may be a programmable non-volatile memory, and the first identification number may be changeable. The controller may be a microcontroller. The first control device may be a multi-chip package.

The test interface board may further include a circuit board including the first division wiring portion and on which the first control device is mounted, wherein the first control device is a semiconductor package.

The plurality of semiconductor devices may each be a semiconductor die, and the plurality of contact portions may each be a needle.

The plurality of semiconductor devices may each be a semiconductor package, and the plurality of contact portions may each be a pogo pin.

In an exemplary embodiment having a plurality of first channels, the number of first division wiring portions may be the same as the number of the plurality of first channels, and the number of the plurality of first contact portions and the number of the first switching devices may each be a plurality of times the number of the plurality of first channels.

The test interface board may further include a second division wiring portion including a second main wiring connected to a second channel of the tester, and a plurality of second sub-wirings divided from the second main wiring. The test interface board may further include a plurality of contact portions that are respectively connected to the plurality of second sub-wirings and respectively contact second electrodes of the plurality of semiconductor devices. The first control device may further include a plurality of second switching devices that are installed in the plurality of sub-wirings, respectively, and the controller of the first control device may control the opening and closing of the plurality of first switching devices and the plurality of second switching devices in response to a control signal corresponding to the first identification number from among the plurality of control signals. The first channel may be a power channel and the plurality of first switching devices may each be a MOS transistor or a relay. The second channel may be one of a data input/output channel, and the plurality of second switching devices may each be one of a bidirectional buffer, a MOS transistor and a relay.

The test interface board may further include a second division wiring portion including a second main wiring connected to a second channel of the tester, and a plurality of sub-wirings divided from the second main wiring. The test interface board may further include a plurality of second contact portions that are respectively connected to the plurality of second sub-wirings and respectively contact second electrodes of the plurality of semiconductor devices. The test interface board may further include a second control device including a plurality of second switching devices that are respectively installed in the plurality of sub-wirings, a memory in which a second identification number is recorded, and a controller for controlling the opening and closing of the plurality of second switching devices in response to a control signal corresponding to the second identification number from among the control signals. The control signal may include identification data corresponding to the first identification number or the second identification number, and the identification data may be transmitted to the first control device and the second control device in parallel.

According to an exemplary embodiment of the inventive concept, there is provided a test interface board including a plurality of control devices. Each of the plurality of control devices may include a plurality of first terminals to which channels of a tester are input, a plurality of second terminals that respectively correspond to the plurality of first terminals and are electrically and respectively connected to electrodes of a plurality of semiconductor devices, a plurality of switching devices that are respectively installed in between the plurality of the first terminals and the second terminals, a memory in which an identification number corresponding to a corresponding control device is recorded from among different identification numbers of the plurality of control devices, and a controller that controls the opening and closing of the plurality of switching devices in response to a control signal corresponding to the identification number from among control signals that are commonly input to the plurality of control devices.

According to an exemplary embodiment of the inventive concept, there is provided a test system including a tester, a first test interface board, and a control signal generator. The first test interface board includes a first division wiring portion including a first main wiring connected to a first channel of the tester, and a plurality of first sub-wirings divided from the first main wiring. The first test interface board may further include a plurality of first contact portions that are respectively connected to the plurality of first sub-wirings and respectively contact first electrodes of a plurality of semiconductor devices. The first test interface board may further include a first control device including a plurality of switching devices that are respectively installed in the plurality of first sub-wirings, a memory in which a first identification number is recorded, and a controller that controls the opening and closing of the plurality of switching devices in response to a control signal corresponding to the first identification number from among a plurality of control signals. The control signal generator generates the plurality of control signals.

According to an exemplary embodiment of the inventive concept, a test interface board includes a first wiring group including a first main wire operatively coupled to a first channel of a tester, and a plurality of first sub-wires operatively coupled to the first main wire. The test interface board further includes a plurality of first contact portions operatively coupled to the plurality of first sub-wires, and contacting first electrodes of a plurality of semiconductor devices. The test interface board further includes a first control device including a plurality of first switching devices operatively coupled to the plurality of first sub-wires, a memory configured to store a first identification number, and a controller configured to open and close the plurality of first switching devices in response to a control signal corresponding to the first identification number from among a plurality of control signals.

According to an exemplary embodiment of the inventive concept a test system includes a tester, a control signal generator generating a plurality of control signals, and a test interface board. The test interface board includes a wiring group including a main wire operatively coupled to a channel of the tester, and a plurality of sub-wires operatively coupled to the main wire. The test interface board further includes a plurality of contact portions operatively coupled to the plurality of sub-wires, and contacting electrodes of a plurality of semiconductor devices. The test interface board further includes a control device including a plurality of switching devices operatively coupled to the plurality of sub-wires, a memory configured to store an identification number, and a controller configured to open and close the plurality of switching devices in response to a control signal corresponding to the identification number from among the plurality of control signals.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a block diagram of a test system, according to an exemplary embodiment of the inventive concept;

FIG. 2 is a block diagram of a test interface board, according to an exemplary embodiment of the inventive concept;

FIG. 3 is a block diagram of a control device, according to an exemplary embodiment of the inventive concept;

FIGS. 4A through 4C are circuit diagrams of switching devices, according to exemplary embodiments of the inventive concept;

FIG. 5 is a block diagram of a test interface board, according to an exemplary embodiment of the inventive concept;

FIG. 6 is a schematic block diagram of an arrangement between a control signal generator and a plurality of control devices, according to an exemplary embodiment of the inventive concept; and

FIG. 7 is a block diagram of a test system, according to an exemplary embodiment of the inventive concept.

### DETAILED DESCRIPTION

Exemplary embodiments of the present inventive concept will be described more fully hereinafter with reference to the accompanying drawings. Like reference numerals may refer to like elements throughout the accompanying drawings.

It will also be understood that when a layer is referred to as being “on” another layer or substrate, it can be directly on the other layer or substrate, or intervening layers may also be present. As used herein, the singular forms “a,” “an” and “the” may include the plural forms as well.

It will further be understood that although the terms first, second, third, etc., may be used herein to describe various elements, components, regions, layers and/or sections, these elements, components, regions, layers and/or sections should not be limited by these terms. As used herein, the teem “and/or” includes any and all combinations of one or more of the associated listed items.

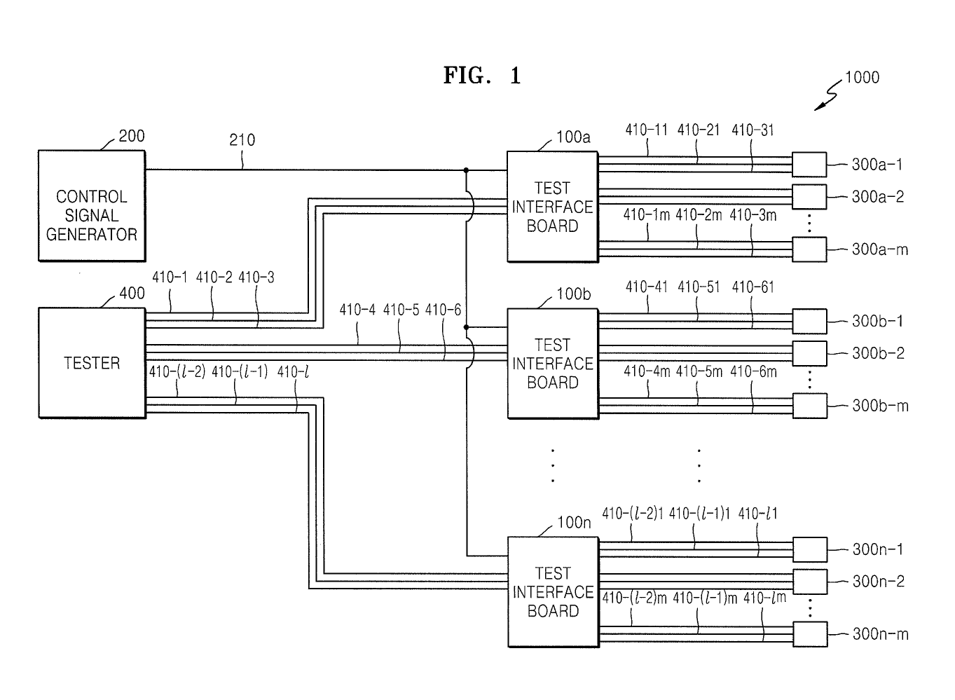

FIG. 1 is a block diagram of a test system 1000 according to an exemplary embodiment of the inventive concept.

Referring to FIG. 1, the test system 1000 includes a tester 400, a control signal generator 200, and test interface boards 100a through 100n. The test system 100 may be used to test semiconductor devices 300a-1, 300a-2, 300a-m, through 300n-m in parallel.

The semiconductor devices 300a-1, 300a-2, 300a-m, through 300n-m are electronic devices that are manufactured using a semiconductor manufacturing process. Each of the semiconductor devices 300a-1, 300a-2, 300a-m, through 300n-m may include individual semiconductor devices such as, for example, diodes, transistors and semiconductor sensors, an integrated circuit (IC), a microprocessor, a memory, and a large scale integrated circuit (LSI). Each of the semiconductor devices 300a-1, 300a-2, 300a-m, through 300n-m may be, for example, a semiconductor package in which a semiconductor die is packaged, a semiconductor die that is not packaged, or a semiconductor wafer that has not been diced to form a semiconductor die.

Each of the semiconductor devices 300a-1, 300a-2, 300a-m, through 300n-m may include power pins or contact pads that supply power to an internal device, and data pins or contact pads that input and output a control signal or a data signal. The pin or contact pad may be collectively referred to as an electrode. Hereinafter, the semiconductor devices 300a-1, 300a-2, 300a-m, through 300n-m may be collectively referred to using reference numeral 300.

The tester 400 includes a plurality of channels 410-1 through 410-l that independently output data signals and power signals according to a stored program or an external command. In the present example, the number of the channels 410-1 through 410-l of the tester 400 is l, and the number of channels required to test a single semiconductor device 300 is 3. However, the inventive concept is not limited thereto, and a plurality of testers may be used to prepare total l channels.

Channels 410-1 through 410-3 of the tester 400 are connected to electrodes of the single semiconductor device 300 to be tested, according to a one-to-one correspondence. However, according to an exemplary embodiment of the inventive concept, channels 410-1 through 410-n may be effectively used by connecting electrodes of a plurality of semiconductor devices 300 to a single channel in parallel. The channels 410-1 through 410-l may be divided into sets of three channels 410-1 through 410-3, 410-4 through 410-6, and 410-(l-2) through 410-l. The three sets of channels 410-1 through 410-3, 410-4 through 410-6, and 410-(l-2) through 410-l are connected to the test interface boards 100a through 100n, respectively. Each of the channels 410-1 through 410-l of the tester 400 may be, for example, a power channel that supplies power, or a data input/output channel that inputs and outputs data.

The test interface boards 100a through 100n may divide the three sets of channels 410-1 through 410-3, 410-4 through 410-6, and 410-(l-2) through 410-l into sets of 3m sub-channels 410-11 through 410-3m, 410-41 through 410-6m, and 410-(l-2)1 through 410-lm. The divided sub-channels 410-11 through 410-lm may be divided into sets of three sub-channels and may be used to test the semiconductor devices 300 rather than channels 410-1 through 410-l of the tester 400.

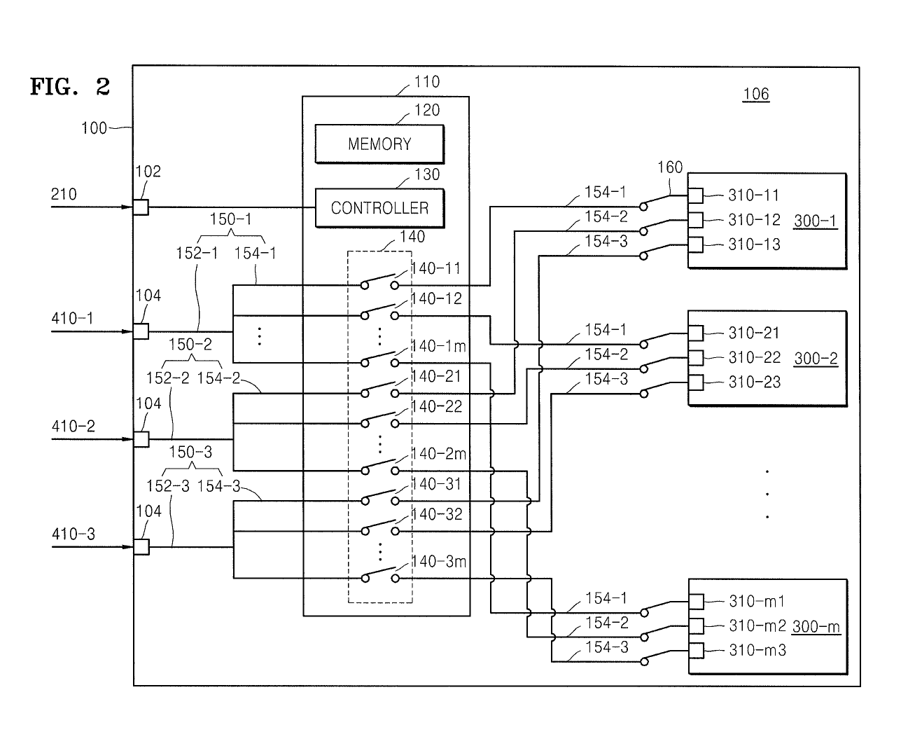

Switching devices may be installed in the sub-channels 410-11 through 410-lm, respectively. The test interface boards 100a through 100n may respectively control the switching devices in response to control signals 210 generated by the control signal generator 200. The control signal generator 200 is described in more detail with reference to FIG. 2. Hereinafter, the test interface boards 100a through 100n may be collectively referred to as reference numeral 100.

The control signal generator 200 generates and provides the control signals 210 to the test interface boards 100a through 100n. The control signals 210 may be provided to the test interface boards 100a through 100n in series using two signal lines +and −, or in parallel using a plurality of signal lines. Although the control signals 210 may be provided to all of the test interface boards 100a through 100n, the test interface boards 100a through 100n may respond only to the control signals 210 respectively assigned to each of the test interface boards 100a through 100n.

In FIG. 1, a plurality of test interface boards 100 are included in the test system 1000. However, as will be understood by one of ordinary skill in the art, the test system 1000 may include a single test interface board 100 connected to the tester 400.

FIG. 2 is a block diagram of a test interface board 100 according to an exemplary embodiment of the inventive concept.

Referring to FIG. 2, the test interface board 100 includes a plurality of wiring groups 150-1 through 150-3, at least one control device 110, and a plurality of contact portions 160 connected to a plurality of semiconductor devices 300-1 through 300-m. The plurality of semiconductor devices 300-1 through 300-m may be disposed on the test interface board 100, or may be disposed separate from and connected to the test interface board 100. In addition, the test interface board 100 may include a control signal input terminal 102 to which the control signal 210 is input, and channel input terminals 104 to which the channels 410-1 through 410-3 are connected. The test interface board 100 may further include a circuit board 106 on which the semiconductor devices 300-1 through 300-m are mounted.

The plurality of wiring groups 150-1 through 150-3 may include main wires 152-1 through 152-3 that are respectively connected to the channels 410-1 through 410-3 of each tester 400, and sub-wires 154-1 through 154-3 that are respectively divided from the main wires 152-1 through 152-3. As shown in FIG. 2, a single main wire (e.g., 152-1) may be divided into sub-wires (e.g., 154-1), which include m switching devices (e.g., 140-11 through 140-1m. Herein, m is a natural number greater than 1 such as, for example, a natural number equal to or greater than 2 and less than or equal to 12. The sub-wires 154-1 through 154-3 may indicate wires positioned at both sides of the control device 110, in particular, switching devices 140-11 through 140-3m. In FIG. 2, the plurality of wiring groups 150-1 through 150-3 are disposed on the circuit board 106, however the location of the plurality of wiring groups 150-1 through 150-3 is not limited thereto. For example, the plurality of wiring groups 150-1 through 150-3 may be included in a wiring layer formed in the control device 110.

The contact portions 160 may be connected to the sub-wires 154-1 through 154-3, respectively, and may be connected to electrodes 310-11 through 310-m3 of the semiconductor devices 300-1 through 300-m, respectively. Thus, the channels 410-1 through 410-3 of the tester 400, which are connected to the main wires 152-1 through 152-3, may be divided into sub-channels via the plurality of wiring groups 150-1 through 150-3, and may be input to the electrodes 310-11 through 310-m3 of the semiconductor devices 300-1 through 300-m via the contact portions 160.

The contact portions 160 may each be, for example, a needle or a pogo pin depending on the types of semiconductor devices 300 being tested. For example, if the semiconductor devices 300 are each a semiconductor die or a semiconductor wafer, the contact portions 160 may each be a needle. In this case, the test interface board 100 may be a probe card. If the semiconductor devices 300 are each a semiconductor package, the contact portions 160 may each be a pogo pin. In addition, the contact portions 160 may correspond to pins of a socket in which the semiconductor package is mounted. In this case, the test interface board 100 may be a hi-fix board used to test the semiconductor package.

The control device 110 may include, for example, a memory 120, a controller 130, and a switching device portion 140. The switching device portion 140 may include, for example, the switching devices 140-11 through 140-3m.

A unique identification number of the control device 110 may be recorded in the memory 120. The memory 120 may be a programmable non-volatile memory such as, for example, a one-time programmable (OTP) memory, a multi-time programmable (MTP) memory, an erasable programmable read only memory (EPROM), or a flash memory. Thus, the identification number may be changed if necessary. For example, as the type of tester 400 and the type of semiconductor devices 300 to be tested are changed, the test interface board 100 may be redesigned. That is, a configuration of the test system 1000 may be changed and/or the number of control devices 110 mounted on the test interface board 100 may be changed. In this case, unique identification numbers of the control devices 110 may be changed to distinguish each of the control devices 100 from each other.

The switching devices 140-11 through 140-3m may be installed in the sub-wires 154-1 through 154-3, and may open or short-circuit the sub-wires 154-1 through 154-3, respectively. When the switching devices 140-11 through 140-3m are short-circuited, the channels 410-1 through 410-3 input through the channel input terminals 104 are connected to the electrodes 310-11 through 310-m3 of the semiconductor devices 300-1 through 300-m via the plurality of wiring groups 150-1 through 150-3 and the contact portions 160, respectively.

The controller 130 controls the opening and closing of the switching devices 140-11 through 140-3m in response to the control signals 210 input through the control signal input terminal 102. In FIG. 2, a single control device 110 is included in a single test interface board 100, however, the inventive concept is not limited thereto. For example, in an exemplary embodiment, a plurality of control devices 110 (e.g., 256 controlling devices 110) may be included in a single test interface board 100.

If a single test interface board 100 includes the plurality of control devices 110, the control devices 110 may include the memory 120, and different unique identification numbers may be recorded in the memory 120 to distinguish each of the plurality of control devices 110 from each other. The control signals 210 may include identification data corresponding to the identification numbers. The controller 130 may respond to only one control signal 210 from among a plurality of control signals 210 that contains identification data corresponding to the identification number recorded in the memory 120. The controller 130 may be a microcontroller such as, for example, a field-programmable gate array (FPGA), a programmable integrated circuit (PIC), or a microcomputer (MICOM).

The memory 120 may be, for example, a separate memory chip. The switching device portion 140 including the switching devices 140-11 through 140-3m may be, for example, a semiconductor chip, and the controller 130 may be, for example, a microcontroller chip. The control device 110 may be, for example, a multi-chip package in which the memory chip, the semiconductor chip, and the microcontroller chip are integrated with each other. In this case, the control device 110 may be surface-mounted on the circuit board 106 using surface mounting technology (SMT) such as, for example, ball grid array (BGA) technology. The control device 110 embodied as a multi-chip package may have a size of about 12 mm×12 mm, however the size of the control device 110 is not limited thereto. Thus, the plurality of control device 110 may be mounted on the single test interface board 100.

If a plurality of semiconductor devices 300 is tested in parallel without utilizing the switching devices 140 described above, a single channel is divided into a plurality of sub-channels, the semiconductor devices 300 are simultaneously tested, and test accuracy may be reduced. Thus, utilization of the switching devices 140 may improve test accuracy.

In addition, if relay devices are mounted directly on a circuit board, and sub-channels divided from the relay devices are opened and closed, additional relay devices may be needed as the number of semiconductor devices to be tested in parallel increases. However, due to the size of each of the relay devices, the circuit board may not have enough space to mount the relay devices. Thus, the number of semiconductor devices to be tested in parallel may be limited. Further, the number of control signals that respectively control the relay devices may also increase in proportion to the number of relay devices utilized, requiring addition space on the circuit board.

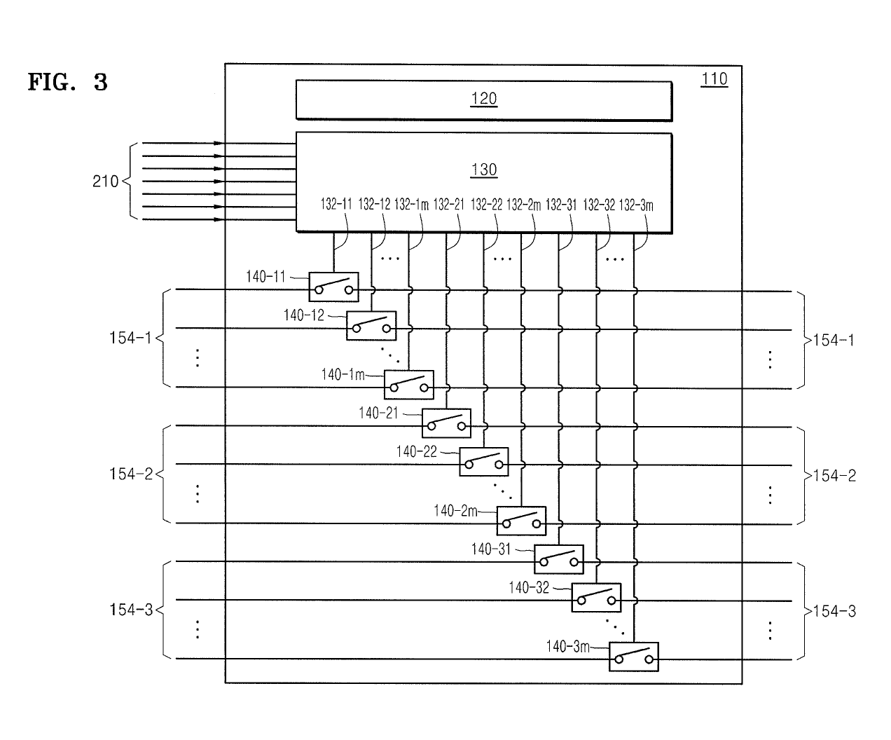

The control device 110 will be described in more detail with reference to FIG. 3.

FIG. 3 is a block diagram of a control device 110 according to an exemplary embodiment of the inventive concept.

Referring to FIG. 3, as described with reference to FIG. 2, the control device 110 includes the memory 120, the controller 130, and the switching devices 140-11 through 140-3m.

As shown in FIG. 3, the controller 130 may receive the control signal 210 in parallel. The control signal 210 may be input to the control device 110 through a plurality of signal lines. For example, as shown in FIG. 3, there may be 7 signal lines, however the number of signal lines is not limited thereto. The control signal 210 may transmit a control command a number of times (e.g., three times) in synchronization with a plurality of clock signals.

For example, the control signal 210 may transmit the identification data in synchronization with a first clock. When there are 7 signal lines, as shown in FIG. 3, the identification data may correspond to a maximum of 2⁷ (128) control devices 110. According to an exemplary embodiment, some bit combinations of the identification data may correspond to 2⁶(64) control devices 110, and the remaining bit combinations may correspond to 2⁶ (64) modes. The modes may include a mode for selecting all of the control devices 110 and a mode for selecting some of the control devices 110. For example, the mode for selecting some of the control devices 110 may include a mode for selecting (even number)ₜₕ control devices 110, (odd number)ₜₕ control devices 110, 4kₜₕ control devices 110, (4k+3)ₜₕ control devices 110, and (12k+7)ₜₕ control devices 110.

Further, the control signal 210 may transmit command data in synchronization with a second clock. For example, the command data may include a command for opening a switch, a command for short-circuiting a switch, a command for opening a switch indefinitely, a command for short-circuiting a switch indefinitely, a command for opening a switch for a predetermined period of time, or a command for short-circuiting a switch for a predetermined period of time. In addition, the command data may include a time corresponding to the predetermined period of time.

The control signal 210 may transmit switching device data for a switching device that corresponds to command data, in synchronization with a third clock. For example, as shown in FIG. 3, when there are 7 signal lines, the switching device data may correspond to a maximum of 2⁷ (128) switching devices 140-11 through 140-3m. According to an exemplary embodiment, some bit combinations of the switching device data may correspond to 2⁶ (64) switching devices 140-11 through 140-3m, and the remaining bit combinations may correspond to 2⁶ (64) modes. The modes may include a mode for selecting all of the switching devices 140-11 through 140-3m and a mode for selecting some of the switching devices 140-11 through 140-3m. For example, the mode for selecting some of the switching devices 140-11 through 140-3m may include a mode for selecting (even number)ₜₕ switching devices, (odd number)ₜₕ switching devices, 4kₜₕ switching devices, (6k+2)ₜₕ switching devices and (12k+11)ₜₕ switching devices.

The inventive concept is not limited to the exemplary embodiments described above with reference to FIGS. 2 and 3. For example, the number of signal lines may be less than or greater than 7, and the control signal 210 may transmit a control command in synchronization with clocks two times or four or more times. In addition, the identification data, the command data, and the switching device data contained in the control signal 210 as described above may be changed in exemplary embodiments. In FIG. 3, the controller 130 receives the control signal 210 in parallel. In an exemplary embodiment, the controller 130 may receive the control signal 210 in series. When the control signal 210 is received in series, the number of signal lines used to transmit the control signal 210 may be further reduced.

The controller 130 receives the control signal 210. The controller 130 may open or close one, some, or all of the switching devices 140-11 through 140-3m in response to a control signal 210 that includes identification data corresponding to a unique identification number of the control device 110. Switch control signals 132-11 through 132-3m may correspond to, and open and close, the switching devices 140-11 through 140-3m, respectively. For example, a positive voltage may be applied to the switch control signals 132-11 through 132-3m, and the switching devices 140-11 through 140-3m corresponding to the switch control signals 132-11 through 132-3m may be short-circuited.

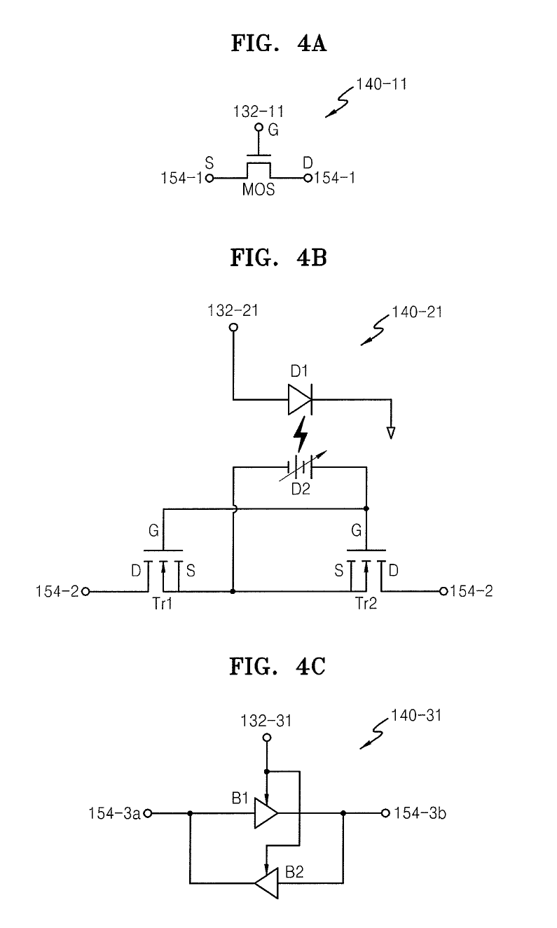

The switching devices 140-11 through 140-3m will be described in more detail with reference to FIGS. 4A through 4C.

FIGS. 4A through 4C are circuit diagrams of switching devices 140-11, 140-21 and 140-31 according to exemplary embodiments of the inventive concept.

Referring to FIG. 4A, the switching device 140-11 may be, for example, a metal-oxide semiconductor (MOS) transistor MOS. Sub-wires 154-1 are connected to a source S and a drain D of the MOS transistor MOS, respectively. A switch control signal 132-11 is input to a gate G of the MOS transistor MOS. When the switch control signal 132-11 has a voltage higher than a threshold voltage of the MOS transistor MOS, the source S and the drain D are connected to each other. Thus, the sub-wires 154-1 are short-circuited, the sub-wires 154-1 have the same potential, and the same current flows along the sub-wires 154-1. The switching device 140-11 embodied as the MOS transistor MOS may be used when a data input/output channel and a power channel that transmit a predetermined voltage and current are transmitted through the sub-wires 154-1.

Referring to FIG. 4B, the switching device 140-21 may be a semiconductor relay (e.g., a solid state relay). The switching device 140-21 may include, for example, a light-emitting diode D1, a photosensor diode D2, and first and second transistors Tr1 and Tr2. A switch control signal 132-21 may be applied to a positive electrode of the light-emitting diode D1, and a negative electrode of the light-emitting diode D1 may be grounded. When the switch control signal 132-21 has a positive voltage, light is generated by the light-emitting diode D1. The light is transmitted to the photosensor diode D2 and generates an electromotive force. The positive electrode of the photosensor diode D2 is connected to gates G of the first transistor Tr1 and the second transistor Tr2. The negative electrode of the photosensor diode D2 is connected to sources S of the first transistor Tr1 and the second transistor Tr2, and substrates. Thus, the first transistor Tr1 and the second transistor Tr2 may be turned on due to the electromotive force, and the sub-wires 154-2 that are respectively connected to drains D of the first transistor Tr1 and the second transistor Tr2 are short-circuited. The switching device 140-21 embodied as a semiconductor relay may be used when a data input/output channel and a power channel that transmits a predetermined voltage and current are transmitted through the sub-wires 154-2. In FIG. 4B, the switching device 140-21 is a semiconductor relay, but is not limited thereto. For example, the switching device 140-21 may be a mechanical relay.

Referring to FIG. 4C, the switching device 140-31 may be a bidirectional buffer. The switching device 140-31 may include a first buffer B1 that transmits data from a first sub-wire 154-3a to a second sub-wire 154-3b, and a second buffer B2 that transmits data from the second sub-wire 154-3b to the first sub-wire 154-3a. The first buffer B1 and the second buffer B2 may be connected in parallel to each other, may be disposed in opposite directions, and may be enabled or disabled by a switch control signal 132-31. When the first buffer B1 and the second buffer B2 are enabled, a channel input to the first sub-wire 154-3a may be transmitted to a semiconductor device through the second sub-wire 154-3b, and output data of the semiconductor device, which is input to the second sub-wire 154-3b, may be transmitted to a tester through the first sub-wire 154-3a. The switching device 140-31 embodied as a bidirectional buffer may be used when a data input/output channel is used through the first and second sub-wires 154-3a and 154-3b.

FIGS. 4A through 4C illustrate examples of the switching devices 140-11 through 140-31. As will be understood by those of ordinary skill in the art, the reference numerals in FIGS. 4A through 4C are used for exemplary purposes, and the types of switches used throughout the test system 1000 are not limited thereto.

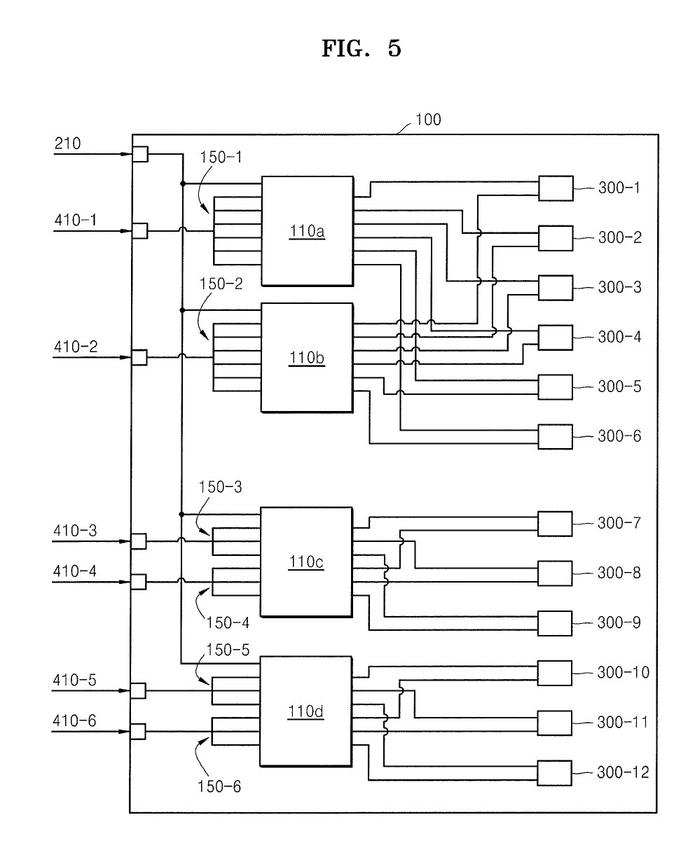

FIG. 5 is a block diagram of a test interface board 100 according to an exemplary embodiment of the inventive concept.

Referring to FIG. 5, the test interface board 100 receives inputs of six channels 410-1 through 410-6, and includes six wiring groups 150-1 through 150-6 and four control devices 110a through 110d. The test interface board 100 may be used to test 12 semiconductor devices 300-1 through 300-12.

The control signal 210 is input in parallel to the four control devices 110a through 110d. As described above, the four control devices 110a through 110d may include memories in which unique identification numbers are recorded, respectively. Thus, the control devices 110a through 110d may receive a plurality of control signals 210, and each control device 110a through 110d may operate in response to the control signal 210 including identification data corresponding to its unique identification number.

From among the six channels 410-1 through 410-6, three channels 410-1, 410-3 and 410-5 may each be a power channel, and the remaining three channels 410-2, 410-4 and 410-6 may each be a data input/output channel.

The control device 110a may control a flow of a plurality of power sub-channels divided from power channel 410-1. In this case, switching devices of the control device 110a may be, for example, a MOS transistor or a semiconductor relay. The power sub-channels may be respectively connected to first electrodes of the first through sixth semiconductor devices 300-1 through 300-6, and may be controlled by the control device 110a.

The control device 110b may control a flow of a plurality of data input/output sub-channels divided from data input/output channel 410-2. In this case, switching devices of the control device 110b may be, for example, a bidirectional buffer, a MOS transistor, or a semiconductor relay. The data input/output sub-channels may be respectively connected to second electrodes of the first through sixth semiconductor devices 300-1 through 300-6, and may be controlled by the control device 110b.

The control device 110c may control both a flow of a plurality of power sub-channels divided from power channel 410-3, and a flow of a plurality of data input/output sub-channels divided from data input/output channel 410-4. In this case, some switching devices of the control device 110c may each be, for example, a MOS transistor or a semiconductor relay, and the remaining switching devices of the control device 110c may be, for example, a bidirectional buffer. Alternatively, all switching devices of the control device 110c may each be, for example, a MOS transistor or a semiconductor relay. The power sub-channels and the data input/output sub-channels may be respectively connected to first electrodes and second electrodes of the seventh through ninth semiconductor devices 300-7 through 300-9, and may be controlled by the control device 110c.

The control device 110d may have a substantially similar structure as that of the control device 110c, however the structure of the control device 110d is not limited thereto.

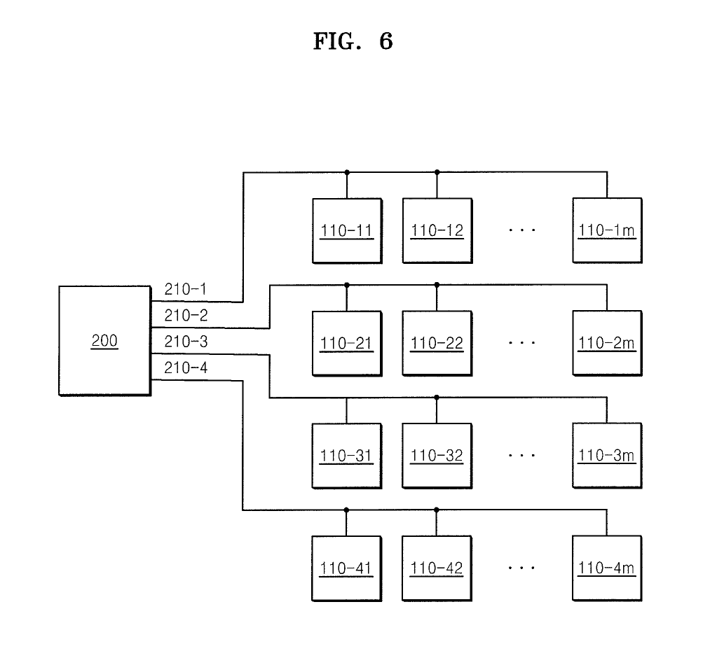

FIG. 6 is a schematic block diagram of an arrangement between a control signal generator 200 and a plurality of control devices 110-11 through 110-4m, according to an exemplary embodiment of the inventive concept.

Referring to FIG. 6, the control signal generator 200 may generate and provide first through fourth control signals 210-1 through 210-4 to the control devices 110-11 through 110-4m. The first control signal 210-1 may be provided to the control devices 110-11 through 110-1m in parallel. The second control signal 210-2 may be provided to the control devices 110-21 through 110-2m in parallel. The third control signal 210-3 may be provided to the control devices 110-31 through 110-3m in parallel. The fourth control signal 210-4 may be provided to the control devices 110-41 through 110-4m in parallel.

The first through fourth control signals 210-1 through 210-4 may control operations of 4m control devices 110-11 through 110-4m. As described above, each of the control devices 110-11 through 110-4m may include a memory in which a unique identification number is recorded, and the first through fourth control signals 210-1 through 210-4 may include identification data corresponding to an identification number of a target device of the control devices 110-11 through 110-4m. The identification numbers may be used to distinguish each of the control devices 110-11 through 110-4m from each other. Thus, each of the control devices 110-11 through 110-4m may identify a target control signal from among the first through fourth control signals 210-1 through 210-4 using the identification data, and may operate in response to only the target control signal.

Although a test interface board is not illustrated in FIG. 6, a test interface board may include the control devices 110-11 through 110-4m. For example, 4m control devices 110-11 through 110-4m may be installed on a single test interface board, or m control devices 110-11 through 110-1m may be installed on a single test interface board.

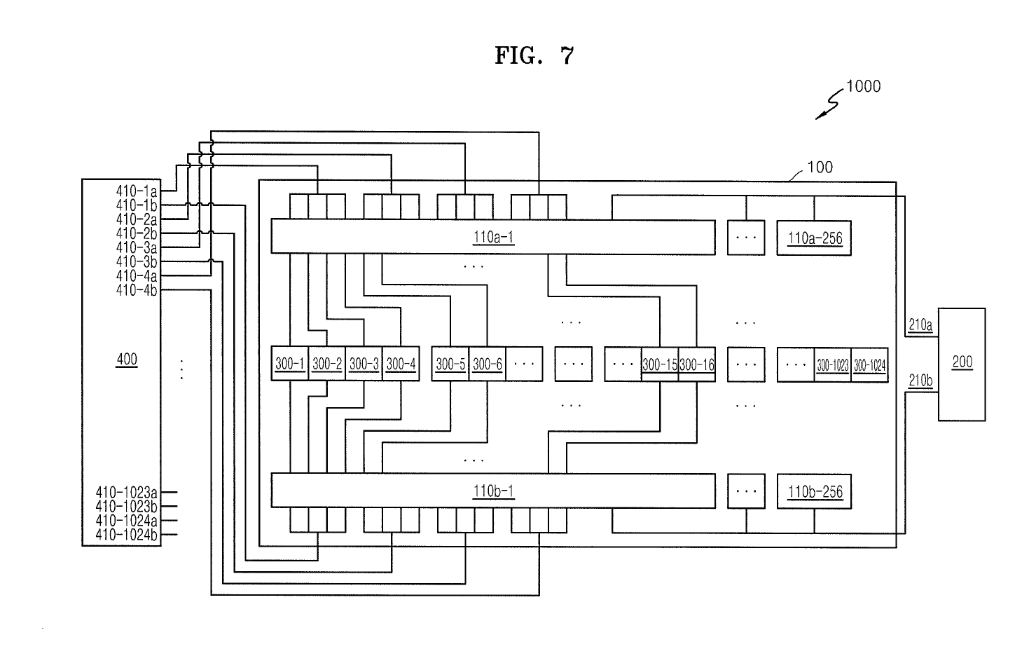

FIG. 7 is a block diagram of a test system 1000 according to an exemplary embodiment of the inventive concept.

Referring to FIG. 7, the test system 1000 is configured to test 1,024 semiconductor devices 300-1 through 300-1024. The tester 400 may provide power channels 410-1a, 410-2a, through 410-1024a, and data input/output channels 410-1b, 410-2b, through 410-1024b. Herein, the data input/output channels 410-1b, 410-2b, through 410-1024b are each illustrated as a single channel. However, a plurality of data input/output channels, for example, four data input/output channels, may be illustrated as a single channel. In this case, the tester 400 may provide 5,120 channels. In order to provide the 5,120 channels, a plurality of testers may be illustrated as the tester 400.

The test interface board 100 may include 512 control devices 110a-1 through 110a-256 and 110b-1 through 110b-256. The control devices 110a-1 through 110a-256 and 110b-1 through 110b-256 may be classified into first type control devices 110a-1 through 110a-256 that control the power channels 410-1a, 410-2a, . . . , through 410-1024a, and second type control devices 110b-1 through 110b-256 that control the data input/output channels 410-1b, 410-2b, through 410-1024b. The first type control devices 110a-1 through 110a-256 may each include 16 power channel switching devices. The second type control devices 110b-1 through 110b-256 may each include 64 data input/output channel switching devices. The power channel switching devices may each be, for example, a MOS transistor or a relay. The data input/output channel switching devices may each be, for example, a bidirectional buffer.

The first type control device 110a-1 may control a flow of 16 power sub-channels divided from four power channels 410-1a through 410-4a. The power sub-channels may be connected to first electrodes of 16 semiconductor devices 300-1 through 300-16. The second type control device 110b-1 may control a flow of 64 data input/output sub-channels divided from 16 data input/output channels 410-1b through 410-4b. The 64 data input/output sub-channels are divided into sets of 4 channels and are connected to four second electrodes of the 16 semiconductor devices 300-1 through 300-16.

The first electrodes and second electrodes of the 1,024 semiconductor devices 300-1 through 300-1024 may be connected to the power sub-channels and the data input/output sub-channels, respectively.

The first type control devices 110a-1 through 110a-256 may be controlled by a first control signal 210a provided by the control signal generator 200. The second type control devices 110b-1 through 100b-256 may be controlled by a second control signal 210b provided by the control signal generator 200.

The test system 1000 may simultaneously test the 1,024 semiconductor devices 300-1 through 300-1024 in parallel.

While the present inventive concept has been particularly shown and described with reference to the exemplary embodiments thereof, it will be understood by those of ordinary skill in the art that various changes in form and detail may be made therein without departing from the spirit and scope of the present inventive concept as defined by the following claims.

1. A test interface board, comprising:
a first wiring group comprising a first main wire operatively coupled to a first channel of a tester, and a plurality of first sub-wires operatively coupled to the first main wire;
a plurality of first contact portions operatively coupled to the plurality of first sub-wires, and contacting first electrodes of a plurality of semiconductor devices; and
a first control device comprising a plurality of first switching devices operatively coupled to the plurality of first sub-wires, a memory configured to store a first identification number, and a controller configured to open and close the plurality of first switching devices in response to a control signal corresponding to the first identification number from among a plurality of control signals.

2. The test interface board of claim 1, wherein the first channel is a power channel, and each of the plurality of first switching devices is one of a metal-oxide semiconductor (MOS) transistor and a relay.

3. The test interface board of claim 1, wherein the first channel is a data input/output channel, and each of the plurality of first switching devices is one of a bidirectional buffer, a metal-oxide semiconductor (MOS) transistor and a relay.

4. The test interface board of claim 1, wherein the memory is a programmable non-volatile memory.

5. The test interface board of claim 1, wherein the controller is a microcontroller.

6. The test interface board of claim 1, wherein the first control device is a multi-chip package.

7. The test interface board of claim 1, further comprising a circuit board, wherein the first wiring group is disposed on the circuit board, and the first control device is a semiconductor package mounted on the circuit board.

8. The test interface board of claim 1, wherein the plurality of semiconductor devices are each a semiconductor die, and the plurality of first contact portions are each a needle.

9. The test interface board of claim 1, wherein the plurality of semiconductor devices are each a semiconductor package, and the plurality of first contact portions are each a pogo pin.

10. The test interface board of claim 1, wherein the first channel is one of a plurality of first channels and the first wiring group is one of a plurality of wiring groups, wherein a number of the wiring groups is equal to a number of the first channels, and a number of the first contact portions and a number of the first switching devices are each greater than the number of the first channels.

11. The test interface board of claim 1, further comprising:
a second wiring group comprising a second main wire operatively coupled to a second channel of the tester, and a plurality of second sub-wires operatively coupled to the second main wire; and
a plurality of second contact portions operatively coupled to the plurality of second sub-wires, and contacting second electrodes of the plurality of semiconductor devices,
wherein the first control device further comprises a plurality of second switching devices operatively coupled to the plurality of second sub-wires, and the controller of the first control device is configured to open and close the plurality of first switching devices and the plurality of second switching devices in response to the control signal corresponding to the first identification number.

12. The test interface board of claim 11, wherein the first channel is a power channel and the plurality of first switching devices are each a MOS transistor or a relay, and
the second channel is a data input/output channel and the plurality of second switching devices are each one of a bidirectional buffer, a MOS transistor and a relay.

13. The test interface board of claim 1, further comprising:
a second wiring group comprising a second main wire operatively coupled to a second channel of the tester, and a plurality of sub-wires operatively coupled to the second main wire;
a plurality of second contact portions operatively coupled to the plurality of second sub-wires, and contacting second electrodes of the plurality of semiconductor devices; and
a second control device comprising a plurality of second switching devices operatively coupled to the plurality of second sub-wires, a memory configured to store a second identification number, and a controller configured to open and close the plurality of second switching devices in response to a control signal corresponding to the second identification number from among the plurality of control signals.

14. The test interface board of claim 13, wherein the plurality of control signals comprise identification data corresponding to the first identification number or the second identification number, and the identification data is transmitted to the first control device and the second control device in parallel.

15. A test system, comprising:
a tester;
a control signal generator configured to generate a plurality of control signals; and
a test interface board comprising:
a wiring group comprising a main wire operatively coupled to a channel of the tester, and a plurality of sub-wires operatively coupled to the main wire;
a plurality of contact portions operatively coupled to the plurality of sub-wires, and contacting electrodes of a plurality of semiconductor devices; and
a control device comprising a plurality of switching devices operatively coupled to the plurality of sub-wires, a memory configured to store an identification number, and a controller configured to open and close the plurality of switching devices in response to a control signal corresponding to the identification number from among the plurality of control signals.

16. The test system of claim 15, wherein the memory is a memory chip, the switching devices are disposed on a semiconductor chip, the controller is a microcontroller chip, and the control device is a multi-chip package comprising the memory chip, the semiconductor chip, and the microcontroller chip.

17-20. (canceled)
